(19) United States
(12) Patent Application Publication
(10) Pub. No.: US 2024/0040713 A1
(43) Pub. Date: Feb. 1, 2024

(54) DISPLAY PANEL AND DISPLAY TERMINAL

(71) Applicant: WUHAN CHINA STAR OPTOELECTRONICS SEMICONDUCTOR DISPLAY TECHNOLOGY CO., LTD., Wuhan (CN)

(72) Inventor: Lidan LI, Wuhan (CN)

(73) Assignee: WUHAN CHINA STAR OPTOELECTRONICS SEMICONDUCTOR DISPLAY TECHNOLOGY CO., LTD., Wuhan (CN)

(21) Appl. No.: 17/622,830

(22) PCT Filed: Dec. 22, 2021
(86) PCT No.: PCT/CN2021/140510

§ 371 Date: Jun. 22, 2023

(30) Foreign Application Priority Data
Dec. 13, 2021 (CN) 202111523004.4

(51) Int. Cl. H05K 5/02

(52) U.S. Cl. CPC H05K 5/02

(57) ABSTRACT

A display panel and a display terminal are provided. A rigid support layer includes a patterned part corresponding to a bending part, and a smooth part corresponding to a non-bending part. The patterned part includes at least one groove and multiple discrete support islands disposed in the groove. Surfaces of the support islands are flush with a surface of the smooth part. Disposing the discrete support islands in the groove can concurrently provide the excellent bending performance and the excellent supporting performance for the rigid support layer.

### FIELD OF INVENTION

This disclosure relates to a display field, and more particularly to a display panel and a display terminal.

### BACKGROUND OF INVENTION

Flexible display devices, such as flexible organic light-emitting diode (OLED) display devices and the like, have been widely used in the life, wherein a backside of an organic light-emitting display panel body is usually provided with a rigid support layer, and a material of the rigid support layer may be the material, such as the stainless steel (SUS) and the like. The rigid support layer can form a support effect for a display panel body and also enhance the bending restorative property of the display panel body, thereby avoiding a crease caused by repeated bending of the flexible material, and enhancing the consumer experience.

However, the too-thin support layer often has the poor support experience effect, and the too-thick support layer cannot be repeatedly bent. Meanwhile, when the display panel is bent, peeling tends to occur between the rigid support layer and other flexible film layers due to the inconsistent deformation, and the rigid support layer tends to break due to the higher rigidity. Therefore, it is necessary to provide a display panel capable of solving the problems of the bending performance and the supporting performance of the rigid support layer, and the problem of the inconsistent performance of the rigid support layer while collocating with other flexible film layers.

### SUMMARY OF INVENTION

### Technical Problems

An embodiment of this disclosure provides a display panel and a display terminal capable of solving the problems of the bending performance and the supporting performance of the existing rigid support layer, and the problem of the inconsistent performance of the existing rigid support layer while collocating with other flexible film layers.

### Technical Solutions

An embodiment of this disclosure provides a display panel, which includes:
a display panel body including at least a bending part and a non-bending part; and
a rigid support layer, which is disposed on a backside of the display panel body and includes a patterned part corresponding to the bending part, and a smooth part corresponding to the non-bending part;
wherein the patterned part includes at least one groove and multiple discrete support islands disposed in the groove, and surfaces of the support islands are flush with a surface of the smooth part away from the display panel body.

Optionally, in some embodiments of this disclosure, the rigid support layer further includes a filling part filled into the groove, a surface of the filling part away from the rigid support layer is flush with the surface of the smooth part, and an elastic modulus of a material of the filling part is less than an elastic modulus of the rigid support layer.

Optionally, in some embodiments of this disclosure, a depth of the groove ranges from ⅓ to ⅔ times of a thickness of the rigid support layer.

Optionally, in some embodiments of this disclosure, the patterned part includes multiple grooves, and the support islands are uniformly arranged.

Optionally, in some embodiments of this disclosure, each of the grooves penetrates through the rigid support layer in a direction parallel to a bending axis.

Optionally, in some embodiments of this disclosure, a cross-sectional shape of the groove includes one or a combination of multiple ones of a square, a rectangle, a triangle, a trapezoid, a semi-circle and a semi-ellipse.

Optionally, in some embodiments of this disclosure, the display panel body includes a first bending part and a second bending part, a bending axis of the first bending part crosses a bending axis of the second bending part, the patterned part includes a first sub-patterned part and a second sub-patterned part, the first sub-patterned part corresponds to the first bending part, and the second sub-patterned part corresponds to the second bending part.

Optionally, in some embodiments of this disclosure, the bending axis of the first bending part is perpendicular to the bending axis of the second bending part.

Optionally, in some embodiments of this disclosure, the first sub-patterned part includes a first groove and a first support island, the second sub-patterned part includes a second groove and a second support island, and the first groove and the second groove are mutually connected together at an intersection of the first sub-patterned part and the second sub-patterned part.

Optionally, in some embodiments of this disclosure, the first sub-patterned part is axisymmetric about the bending axis of the first bending part; and the second sub-patterned part is axisymmetric about the bending axis of the second bending part.

Optionally, in some embodiments of this disclosure, a shape of the first support island is the same as a shape of the second support island.

Optionally, in some embodiments of this disclosure, each of the first support island and the second support island both have an axisymmetric shape about the bending axis of the first bending part; and each of the first support island and the second support island both have an axisymmetric shape about the bending axis of the second bending part.

Optionally, in some embodiments of this disclosure, the first sub-patterned part has a centrosymmetric structure, and the second sub-patterned part has a centrosymmetric structure.

Optionally, in some embodiments of this disclosure, the groove is disposed on one side of the rigid support layer away from the display panel body.

Optionally, in some embodiments of this disclosure, the material of the filling part is a hot melt glue.

Correspondingly, an embodiment of this disclosure further provides a display terminal including a main terminal body and a display panel, wherein the main terminal body and the display panel are combined together as a whole. The display panel includes:
a display panel body including at least a bending part and a non-bending part; and
a rigid support layer, which is disposed on a backside of the display panel body and includes a patterned part corresponding to the bending part, and a smooth part corresponding to the non-bending part;
wherein the patterned part includes at least one groove and multiple discrete support islands disposed in the groove, and surfaces of the support islands are flush with a surface of the smooth part away from the display panel body.

Optionally, in some embodiments of this disclosure, the rigid support layer further includes a filling part filled into the groove, a surface of the filling part away from the rigid support layer is flush with the surface of the smooth part, and an elastic modulus of a material of the filling part is less than an elastic modulus of the rigid support layer.

Optionally, in some embodiments of this disclosure, the display panel body includes a first bending part and a second bending part, a bending axis of the first bending part crosses a bending axis of the second bending part, the patterned part includes a first sub-patterned part and a second sub-patterned part, the first sub-patterned part corresponds to the first bending part, and the second sub-patterned part corresponds to the second bending part.

Optionally, in some embodiments of this disclosure, the first sub-patterned part is axisymmetric about the bending axis of the first bending part; and the second sub-patterned part is axisymmetric about the bending axis of the second bending part.

Optionally, in some embodiments of this disclosure, the first sub-patterned part has a centrosymmetric structure, and the second sub-patterned part has a centrosymmetric structure.

### Beneficial Effects

In the embodiment of this disclosure, the display panel and the display terminal are provided, the rigid support layer is disposed on the backside of the display panel body, and the rigid support layer includes a patterned part corresponding to the bending part and a smooth part corresponding to the non-bending part. The patterned part includes at least one groove and multiple discrete support islands disposed in the groove, and surfaces of the support islands are flush with a surface of the smooth part. Disposing the discrete support islands in the groove can concurrently provide the excellent bending performance and the excellent supporting performance for the rigid support layer, and the good collocation coordination between the rigid support layer and other flexible film layers.

### DESCRIPTION OF DRAWINGS

In order to explain the technical solution in this disclosure more clearly, the drawings required for the description of the embodiments will be briefly introduced. Obviously, the drawings in the following description only relate to some embodiments of this disclosure. Other drawings can be obtained from these drawings without creative works.

FIG. 1 is a first schematic cross-section view showing a display panel provided by an embodiment of this disclosure before bending.

FIG. 2 is a second schematic cross-section view showing a display panel provided by an embodiment of this disclosure before bending.

FIG. 3 is a first schematic top view showing a rigid support layer provided by an embodiment of this disclosure.

FIG. 4 is a schematic cross-section view showing a display panel provided by an embodiment of this disclosure after bending.

FIG. 5 is a second schematic top view showing a rigid support layer provided by an embodiment of this disclosure.

FIG. 6 is a third schematic top view showing a rigid support layer provided by an embodiment of this disclosure.

FIG. 7 is a first schematic cross-section view showing a rigid support layer provided by an embodiment of this disclosure.

FIG. 8 is a second schematic cross-section view showing a rigid support layer provided by an embodiment of this disclosure.

FIG. 9 is a third schematic cross-section view showing a rigid support layer provided by an embodiment of this disclosure.

FIG. 10 is a schematic top view showing a display panel body provided by an embodiment of this disclosure.

FIG. 11 is a fourth schematic top view showing a rigid support layer provided by an embodiment of this disclosure.

FIG. 12 is a schematic enlarged view showing a support island provided by an embodiment of this disclosure.

FIG. 13 is a schematic view showing a display terminal provided by an embodiment of this disclosure.

### DETAILED DESCRIPTION OF EMBODIMENTS

The technical solutions in the embodiments of this disclosure will be clearly and completely described in the following with reference to the drawings of the embodiments of this disclosure. Obviously, the described embodiments are only a part of the embodiments of this disclosure, rather than all the embodiments. Based on the embodiments of this disclosure, all other embodiments obtained by those skilled in the art without creative works are deemed as falling within the scope of this disclosure. In addition, it should be understood that the specific implementations described herein are only used to illustrate and explain this disclosure, and are not used to limit this disclosure. In this disclosure, unless explanation is made to the contrary, the orientation words, used such as “upper” and “lower,” generally refer to the upper and lower positions of the device in an actual use or working state, and specifically refer to the drawing directions in the drawings; and “inner” and “outer” refer to the outline of the device.

An embodiment of this disclosure provides a display panel including: a display panel body including at least a bending part and a non-bending part; a rigid support layer, which is disposed on a backside of the display panel body and includes a patterned part corresponding to the bending part, and a smooth part corresponding to the non-bending part. The patterned part includes at least one groove and multiple discrete support islands disposed in the groove, and surfaces of the support islands are flush with a surface of the smooth part.

An embodiment of this disclosure provides a display panel and a display terminal. Detailed descriptions will be respectively made in the following. It should be noted that the order of descriptions in the following embodiments is not intended to limit the preferred order of the embodiments.

### First Embodiment

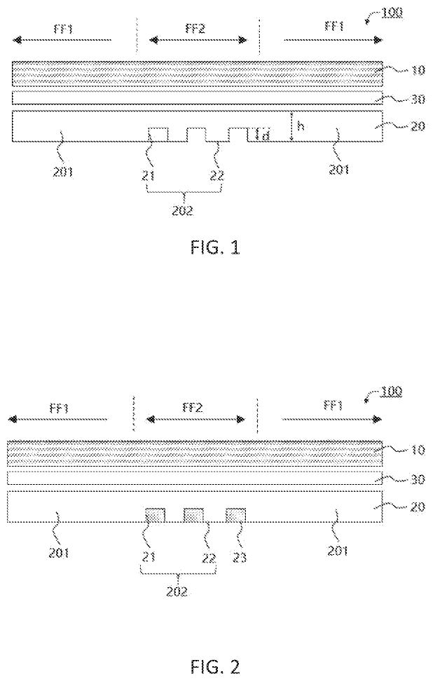

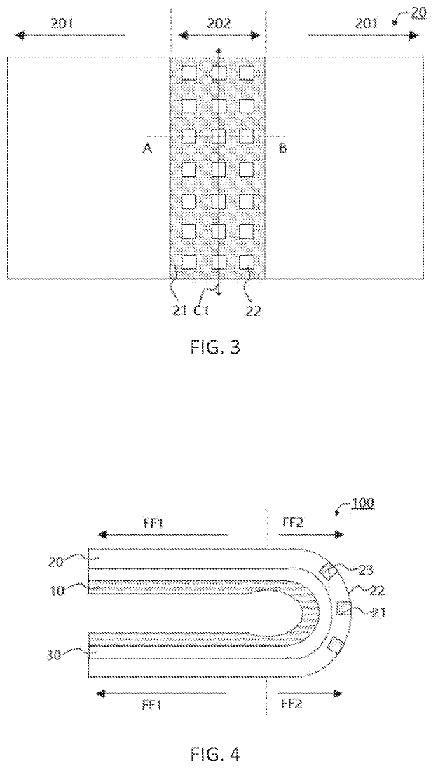

Please refer to FIGS. 1 to 4. FIG. 1 is a first schematic cross-section view showing a display panel 100 before bending provided by an embodiment of this disclosure. FIG. 2 is a second schematic cross-section view showing the display panel 100 before bending provided by an embodiment of this disclosure. FIG. 3 is a first schematic top view showing a rigid support layer 20 provided by an embodiment of this disclosure. FIG. 4 is a schematic cross-section view showing the display panel 100 after bending provided by an embodiment of this disclosure.

An embodiment of this disclosure provides the display panel 100 including a display panel body 10 and the rigid support layer 20. The display panel body 10 includes at least a bending part FF2 and a non-bending part FF1. The rigid support layer 20 is disposed on a backside of the display panel body 10, and includes a patterned part 202 corresponding to the bending part FF2, and a smooth part 201 corresponding to the non-bending part FF1. The patterned part 202 includes at least one groove 21 and multiple discrete support islands 22 disposed in the groove 21, and surfaces of the support islands 22 are flush with a surface of the smooth part 201 away from the display panel body 10.

Specifically, the display panel body 10 may include an array substrate, a light-emitting device layer disposed on the array substrate and an encapsulation layer disposed on the light-emitting device layer, and the structure of the display panel body 10 is not limited thereto.

Specifically, the display panel body 10 may display an image. The display panel body 10 may be an organic light-emitting display panel body, but is not limited thereto. For example, the display panel body 10 may also be a liquid crystal display panel body.

Specifically, a display side of the display panel body 10 is one side, which displays an image or is observed by the human eyes, wherein one side away from or opposite to the display side of the display panel body 10 is a backside or non-display side of the display panel body 10.

Specifically, the backside of the display panel body 10 is provided with the rigid support layer 20, wherein a material of the rigid support layer 20 may be a stainless steel (SUS), but is not limited thereto.

Specifically, the display panel 100 may further include a flexible support layer 30, which may include one or multiple ones of a backpanel layer, a buffer layer and the like. A material of the backpanel layer may be polyimide and the like. A material of the buffer layer may be foam and the like.

Specifically, the display panel body 10 includes at least the bending part FF2 and the non-bending part FF1. The display panel body 10 may include two non-bending parts FF1, and the bending part FF2 is disposed between the two non-bending parts FF1, so that the display panel 100 can be folded or bent about a bending axis of the bending part FF2.

Specifically, the rigid support layer 20 includes the patterned part 202 corresponding to the bending part FF2, and the smooth part 201 corresponding to the non-bending part FF1. The patterned part 202 includes at least one groove 21 and multiple discrete support islands 22 disposed in the groove 21. The surfaces of the support islands 22 are flush with the surface of the smooth part 201 away from the display panel body 10. That is, the patterned part 202 includes a thinning region of the rigid support layer 20, the groove 21 is the thinning region of the rigid support layer 20, and the support island 22 is a region of the patterned part 202, which is not thinned down.

Specifically, the patterned part 202 includes at least one groove 21 and multiple discrete support islands 22, which are disposed at intervals or separately and for providing the support effect for the display panel body 10.

Specifically, the groove 21 may provide the rigid support layer 20 with the good bending performance.

Specifically, the groove 21 collocates with the discrete support islands 22. In the bending process, the inconsistent deformation between the rigid support layer 20 and other flexible film layers may be reduced, so that the peeling is reduced, and the rigid support layer 20 cannot be easily broken.

In some embodiments, a depth of the groove 21 ranges from ⅓ to ⅔ times of a thickness of the rigid support layer 20.

Specifically, as shown in FIG. 1, a depth d of the groove 21 is a thickness of the rigid support layer 20 thinned down in the region of the groove. An appropriate depth of the groove 21 is selected to guarantee that the rigid support layer 20 at the portion of the groove 21 concurrently has the good bending performance and supporting performance, and has the structural strength of the connection to each support island 22. Preferably, the depth d of the groove 21 ranges from ⅓ to ⅔ times of a thickness h of the rigid support layer 20, so that the requirements of these performances can be satisfied, and the depth d of the groove 21 cannot become too large or too small.

In the embodiment of this disclosure, disposing the discrete support islands 22 in the groove 21 in the rigid support layer 20 can concurrently provide the rigid support layer with the excellent bending performance and the excellent supporting performance, and provide the good collocation coordination between the rigid support layer and the flexible film layer.

### Second Embodiment

This embodiment is the same as or similar to the above-mentioned embodiment except for the difference that the structure of the groove 21 is further depicted.

In some embodiments, the rigid support layer 20 further includes a filling part 23 filled into the groove 21, wherein a surface of the filling part 23 away from the rigid support layer 20 is flush with the surface of the smooth part 201, and an elastic modulus of a material of the filling part 23 is less than an elastic modulus of the rigid support layer 20.

Specifically, as shown in FIG. 2 and compared to the above-mentioned embodiment, the groove 21 of the rigid support layer 20 is provided with the filling part 23, and the elastic modulus of the material of the filling part 23 is less than the elastic modulus of the rigid support layer 20.

Specifically, because the elastic modulus of the material of the filling part 23 is less than the elastic modulus of the rigid support layer 20, the filling part 23 also deforms in the bending or folding process. As shown in FIG. 4, the filling part 23 can have the larger deformation than the support island 22 to provide the function of buffering the rigid support layer 20 or the function of increasing the local toughness of the rigid support layer 20, so that the inconsistent deformation between the rigid support layer 20 and other flexible film layers is reduced, the peeling is reduced, and the rigid support layer 20 cannot be easily broken.

Specifically, the filling part 23 is disposed in the groove 21. When the surfaces of the support islands 22 of the rigid support layer 20 are bonded to other layer structures, the surface of the filling part 23 away from the rigid support layer 20 is flush with the surface of the smooth part 201 to provide the patterned part 202 with a flat or substantially flat surface and to enhance the stacking and bonding performances between the rigid support layer 20 and other layer structures.

In some embodiments, the material of the filling part 23 is a hot melt glue.

Specifically, the hot melt glue has the liquidity at a high temperature, and solidifies into a solid at a room temperature. The hot melt glue can be easily disposed to be flush with the surface of the filling part 23 away from the rigid support layer 20 and the surface of the smooth part 201.

Specifically, the filling part 23 may also be other organic substances.

Specifically, an elastic modulus of the hot melt glue is less than the elastic modulus of the rigid support layer 20 to provide the rigid support layer 20 with a buffer deformation effect and an effect of increasing the toughness.

### Third Embodiment

This embodiment is the same as or similar to the above-mentioned embodiment except for the difference that a structural shape of another patterned part is depicted.

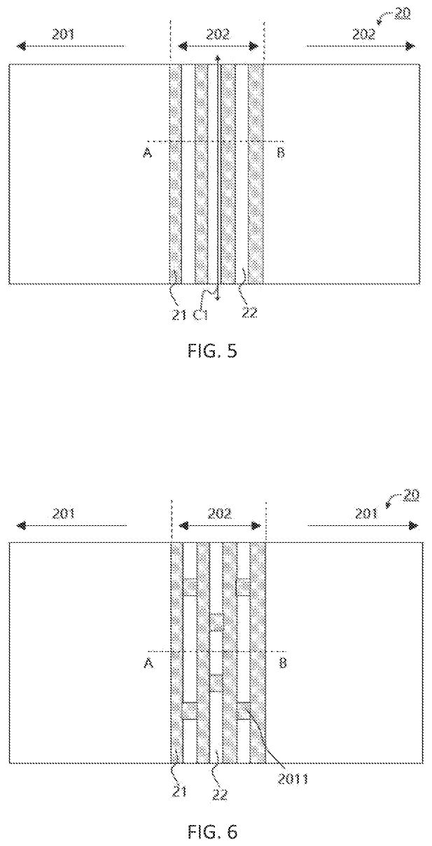

Please refer to FIGS. 5 and 6. FIG. 5 is a second schematic top view showing the rigid support layer 20 provided by an embodiment of this disclosure. FIG. 6 is a third schematic top view showing the rigid support layer 20 provided by an embodiment of this disclosure.

In some embodiments, the patterned part 202 includes multiple grooves 21, and the multiple support islands 22 are uniformly arranged.

Specifically, please refer jointly to FIGS. 3, 5 and 6. The patterned part 202 includes multiple grooves 21, and the support islands 22 are uniformly arranged so that the support islands 22 provide the display panel body 10 with the uniform support.

Specifically, in some embodiments, the patterned part 202 includes multiple grooves 21 mutually connected together.

In some embodiments, each of the grooves 21 penetrates through the rigid support layer in a direction parallel to a bending axis C1.

Specifically, as shown in FIGS. 5 and 3, the groove 21 penetrates through the rigid support layer 20 in the direction parallel to the bending axis C1.

Specifically, as shown in FIGS. 6 and 3, the grooves 21 are mutually connected together through a connection slot 2011, wherein a structure and a depth of the connection slot 2011 are the same as or similar to those of the groove 21, and the connection slot 2011 may also be understood as subordinating to the groove 21.

Specifically, the grooves 21 are mutually connected together through the connection slot 2011. When the rigid support layer 20 includes the filling parts 23, the filling parts 23 are mutually connected together in two or more than two directions to provide the rigid support layer 20 with a buffer deformation effect and an effect of increasing the toughness in two or more than two directions.

Specifically, it is easily understood that FIGS. 3 and 6 may be regarded as having multiple grooves 21 mutually connected together, or may be regarded as a groove 21 having an irregular shape as a whole.

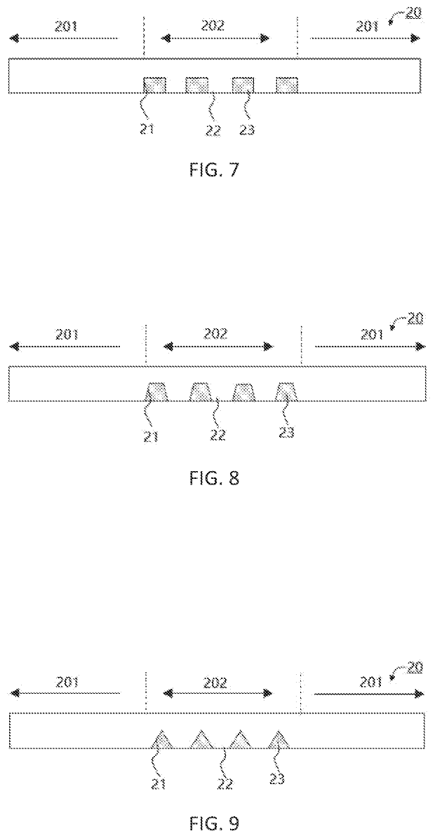

Please refer to FIGS. 7 to 9. FIG. 7 is a first schematic cross-section view showing the rigid support layer 20 provided by an embodiment of this disclosure. FIG. 8 is a second schematic cross-section view showing the rigid support layer 20 provided by an embodiment of this disclosure. FIG. 9 is a third schematic cross-section view showing the rigid support layer 20 provided by an embodiment of this disclosure. FIGS. 7 to 9 are cross-sectional views taken along dashed lines A-B in FIGS. 3, 5 and 6.

In some further embodiments, a cross-sectional shape of the groove 21 includes one or a combination of multiple ones of a square, a rectangle, a triangle, a trapezoid, a semi-circle and a semi-ellipse.

FIG. 7 schematically illustrates the cross-sectional shape of the groove 21 being the square or rectangle. FIG. 8 schematically illustrates the cross-sectional shape of the groove 21 being the trapezoid. FIG. 9 schematically illustrates the cross-sectional shape of the groove 21 being the triangle.

Specifically, when the shape of the groove 21 or the shape of the filling part 23 is configured, it is possible to configure the cross-sectional shape of the groove 21 as including at least one of the square, the rectangle, the triangle, the trapezoid, the semi-circle and the semi-ellipse, or to configure the cross-sectional shape of the groove 21 as including the combination of multiple ones of the square, the rectangle, the triangle, the trapezoid, the semi-circle and the semi-ellipse. These shapes can be easily formed, and can further concurrently provide the rigid support layer with the excellent bending performance, the excellent supporting performance, and the good collocation coordination between the rigid support layer and the flexible film layer.

Specifically, referring jointly to the cross-sectional views of FIGS. 7 to 9, the cross-sectional shape of the support island 22 may be the rectangle, the trapezoid, the triangle and the like. For example, in FIG. 9, when the adjacent grooves 21 are disposed in a contacting manner, the cross-sectional shape of the support island 22 is the triangle, and the support island 22 may provide the uniform support for the display panel body 10. In this embodiment, multiple top-view and cross-section structures of the patterned parts 202 of the rigid support layers 20 are provided, and the diversified configurations of the rigid support layers 20 are provided. Upon configuring the product, one or multiple ones of the configurations can be selected therefrom to concurrently provide the rigid support layer with the excellent bending performance, the excellent supporting performance, and the good collocation coordination between the rigid support layer and other flexible film layers.

### Fourth Embodiment

This embodiment is the same as or similar to the above-mentioned embodiment except for the difference that the display panel body 10 includes more than one bending part FF2, and the rigid support layer 20 includes more than one patterned part 202.

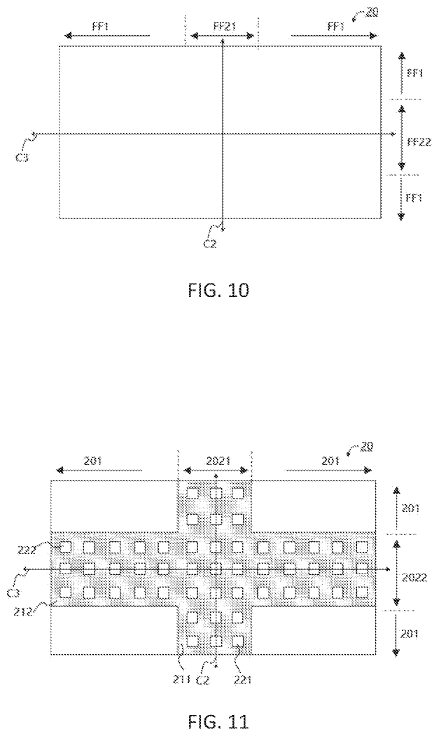

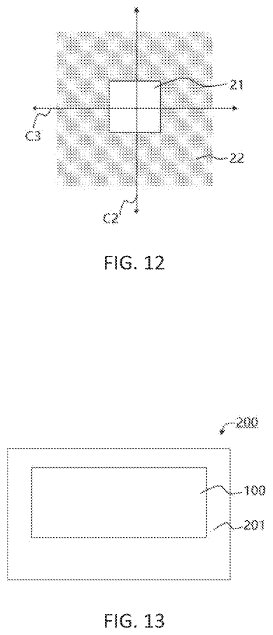

Please refer to FIGS. 10 to 12. FIG. 10 is a schematic top view showing a display panel body provided by an embodiment of this disclosure. FIG. 11 is a fourth schematic top view showing the rigid support layer 20 provided by an embodiment of this disclosure. FIG. 12 is a schematic enlarged view showing a support island 21 provided by an embodiment of this disclosure.

In some embodiments, the display panel body 10 includes a first bending part FF21 and a second bending part FF22. A bending axis C2 of the first bending part FF21 crosses a bending axis C3 of the second bending part FF22. The patterned part 202 includes a first sub-patterned part 2021 and a second sub-patterned part 2022. The first sub-patterned part 2021 corresponds to the first bending part FF21, and the second sub-patterned part 2022 corresponds to the second bending part FF22.

Specifically, in some embodiments, the display panel body 10 includes more than one bending part FF2, or the display panel body 10 includes the first bending part FF21 and the second bending part FF22.

Specifically, the first bending part FF21 is disposed between two non-bending parts FF1, and the second bending part FF22 is disposed between the two non-bending parts FF1.

Specifically, the bending axis C2 of the first bending part FF21 crosses the bending axis C3 of the second bending part FF22, and the display panel 100 can be bent or folded at the first bending part FF21 and the second bending part FF22 crossing each other.

Specifically, the patterned part 202 includes the first sub-patterned part 2021 and the second sub-patterned part 2022, the first sub-patterned part 2021 is disposed between two smooth parts 201, and the second sub-patterned part 2022 is disposed between the two smooth parts 201.

Specifically, the first sub-patterned part 2021 corresponds to the first bending part FF21, and the second sub-patterned part 2022 corresponds to the second bending part FF22. Each of the first sub-patterned part 2021 and the second sub-patterned part 2022 includes the groove 21 and the support islands 22 in any one of the above-mentioned embodiments, or includes the groove 21, the support island 22 and the filling part 23 in any one of the above-mentioned embodiments. In the rigid support layer 20, the bending parts in two cross directions concurrently provide the rigid support layer 20 with the excellent bending performance, the excellent supporting performance, and the good collocation coordination between the rigid support layer and other flexible film layers.

It is to be described that in the above-mentioned embodiment, when the display panel body 10 includes one bending part FF2, the cross-sectional shape of the groove 21 includes one or a combination of multiple ones of the square, the rectangle, the triangle, the trapezoid, the semi-circle and the semi-ellipse. In this embodiment, the display panel body 10 includes more than one bending part FF2, and the rigid support layer 20 includes more than one patterned part 202. Preferably, the cross-sectional shape of the groove 21 includes at least one or a combination of multiple ones of the square, the rectangle, the trapezoid, the semi-circle and the semi-ellipse, and the cross-sectional shape of the groove 21 is not suitable for the triangle. This is because the triangular cross-sectional shape of the groove 21 cannot provide the gentle transition between the cross-sections in the two directions and cannot decrease the stress concentration in the cross-section parallel to the bending axis C2 of the first bending part FF21 and in the cross-section parallel to the bending axis C3 of the second bending part FF22.

In some embodiments, the bending axis C2 of the first bending part FF21 is further perpendicular to the bending axis C3 of the second bending part FF22.

Specifically, the bending axis C2 of the first bending part FF21 is perpendicular to the bending axis C3 of the second bending part FF22, so that the first sub-patterned part 2021 and the second sub-patterned part 2022 are also in a mutually perpendicular or substantially perpendicular state. A preferred bending method is provided.

Further, in some embodiments, the first sub-patterned part 2021 includes a first groove 211 and a first support island 221. The second sub-patterned part 2022 includes a second groove 212 and a second support island 222. The first groove 211 and the second groove 212 are mutually connected together at an intersection between the first sub-patterned part 2021 and the second sub-patterned part 2022.

Specifically, as shown in FIG. 11, the first groove 211 and the second groove 212 are mutually connected together at an intersection between the first sub-patterned part 2021 and the second sub-patterned part 2022. That is, thinned parts mutually connected together are disposed at the intersection between the first sub-patterned part 2021 and the second sub-patterned part 2022. When the display panel 100 is bent or folded at the first bending part FF21 and the second bending part FF22, the excellent bending performance, the excellent supporting performance, and the good collocation coordination between the rigid support layer and the flexible film layer are provided to the rigid support layer 20 at the intersection of the first sub-patterned part 2021 and the second sub-patterned part 2022.

In some embodiments, the first sub-patterned part 2021 is axisymmetric about the bending axis C2 of the first bending part FF21, and the second sub-patterned part 2022 is axisymmetric about the bending axis C3 of the second bending part FF22.

Specifically, when the display panel 100 is bent along the first bending part FF21 or/and the first sub-patterned part 2021, the first sub-patterned part 2021 is axisymmetric about the bending axis C2 of the first bending part FF21, and the display panel 100 can be bent symmetrically or uniformly. So, the bending deformation and the stress concentration distribution of the rigid support layer 20 are symmetrical or uniform to provide the rigid support layer with the excellent bending performance, the excellent supporting performance, and the good collocation coordination between the rigid support layer and the flexible film layer.

Specifically, when the display panel 100 is bent along the second bending part FF22 or/and the second sub-patterned part 2022, the second sub-patterned part 2022 is axisymmetric about the bending axis C3 of the second bending part FF2, and the display panel 100 can be bent symmetrically or uniformly, so that the bending deformation and the stress concentration distribution of the rigid support layer 20 are symmetrical or uniform to provide the rigid support layer with the excellent bending performance, the excellent supporting performance, and the good collocation coordination between the rigid support layer and the flexible film layer.

In some embodiments, a shape of the first support island 221 is the same as a shape of the second support island 222.

Specifically, the shape of the first support island 221 is the same as the shape of the second support island 222, so that the minimum stress concentration is obtained to enhance the bending performance when the display panel 100 is bent along the first bending part FF21 and the second bending part FF22.

In some embodiments, each of the first support island 221 and the second support island 222 both have an axisymmetric shape about the bending axis C2 of the first bending part FF21. The first support island 221 and the second support island 222 have the axisymmetric shapes about the bending axis C3 of the second bending part FF22.

Specifically, as shown in FIG. 12, each of the first support island 221 and the second support island 222 both have an axisymmetric shape about the bending axis C2 of the first bending part FF21, and each of the first support island 221 and the second support island 222 both have an axisymmetric shape about the bending axis C3 of the second bending part FF22. Thus, when the display panel 100 is bent at the first bending part FF21 or the second bending part FF22, the stresses exerted onto the first support island 221 and the second support island 222 in two bending directions approach each other, or are the minimum/smaller stresses in the two bending directions, thereby enhancing the bending performance of the rigid support layer 20. Meanwhile, the uniform support effects of the first sub-patterned part 2021 and the second sub-patterned part 2022 to the display panel body are obtained, and the best supporting performance is achieved, so that the flat resilience of the surface of the display panel body 10 is uniform and that the display panel 100 can provide the image having the excellent quality.

Specifically, shapes of the surfaces of the first support island 221 and the second support island 222 may include one of a square, a circle, a rhombus, a regular polygon and the like.

In some embodiments, the first sub-patterned part 2021 has a centrosymmetric structure, and the second sub-patterned part 2022 has a centrosymmetric structure.

Specifically, the first sub-patterned part 2021 has the centrosymmetric structure, so that the stress exerted onto the first sub-patterned part 2021 is minimum and has the uniform distribution when the display panel 100 is bent at the first bending part FF21, thereby enhancing the bending performance of the rigid support layer 20. The second sub-patterned part 2022 has the centrosymmetric structure, so that the display panel 100 is bent at the second bending part FF22, the stress exerted onto the second sub-patterned part 2022 is minimum and has the uniform distribution, thereby enhancing the bending performance of the rigid support layer 20. Meanwhile, the support effects of the first sub-patterned part 2021 and the second sub-patterned part 2022 to the display panel body 10 are uniform to achieve the best supporting performance, so that the flat resilience of the surface of the display panel body 10 is uniform, and that the display panel 100 can provide the image having the excellent quality.

### Fifth Embodiment

This embodiment is the same as or similar to the above-mentioned embodiment except for the difference that the orientation of the patterned part 202 in the display panel 100 is restricted.

In some embodiments, the groove 21 in the display panel 100 is disposed on one side of the rigid support layer 20 away from the display panel body 10.

Specifically, in the display panel 100 of the above-mentioned embodiment as shown in FIGS. 1 and 2, when the display panel 100 is bent, the rigid support layer 20 is away from the display panel body 10, the deformation or stress concentration generated in the rigid support layer 20 is larger, and one side or surface of the rigid support layer 20 away from the display panel body 10 is farthest from the display panel body 10. The deformation or stress concentration generated on the one side or surface of the rigid support layer 20 away from the display panel body 10 becomes maximum. The groove 21 is disposed on one side of the rigid support layer 20 away from the display panel body 10. That is, the groove 21 and the support island 22 are disposed on a surface of one side of the rigid support layer away from the display panel body 10. The stress concentration and the deformation amount generated in the rigid support layer 20 can be decreased to provide the rigid support layer with the excellent bending performance, the excellent supporting performance, and the good collocation coordination between the rigid support layer and the flexible film layer.

### Sixth Embodiment

Please refer to FIG. 13. FIG. 13 is a schematic view showing a display terminal 200 provided by an embodiment of this disclosure.

In the embodiment of this disclosure, the display terminal 200 is further provided. The display terminal 200 includes a main terminal body 201 and the display panel 100 in any one of the above-mentioned embodiments, and the main terminal body 201 and the display panel 100 are combined together as a whole.

Specifically, the display terminal 200 may be a mobile phone, a notebook computer, a television and the like.

In the above-mentioned embodiments, it should be noted that disposing the discrete support islands 22 can discretize the structure continuity of the rigid support layer in the bending direction so that the problem of the too high bending stress of the rigid support layer 20 is solved, and disposing the filling part 23 in the groove 21 can solve the problem of the poor flatness of the patterned part 202.

Detailed introductions of the display panel and the display terminal provided by an embodiment of this disclosure have been made. In this disclosure, specific examples are used to explain the principles and implementation of this disclosure. The descriptions of the above-mentioned embodiments are only used to help the understanding of the method and core idea of this disclosure. Meanwhile, those skilled in the art will make changes to the specific implementation and the application scope according to the idea of this disclosure. In summary, the contents of this specification should not be construed as a limitation to this disclosure.

What is claimed is:

1. A display panel, comprising:
a display panel body comprising at least a bending part and a non-bending part; and
a rigid support layer disposed on a backside of the display panel body and comprising a patterned part corresponding to the bending part, and a smooth part corresponding to the non-bending part;
wherein the patterned part comprises at least one groove and multiple discrete support islands disposed in the groove, and surfaces of the support islands are flush with a surface of the smooth part away from the display panel body.

2. The display panel according to claim 1, wherein the rigid support layer further comprises a filling part filled into the groove, a surface of the filling part away from the rigid support layer is flush with the surface of the smooth part, and an elastic modulus of a material of the filling part is less than an elastic modulus of the rigid support layer.

3. The display panel according to claim 1, wherein a depth of the groove ranges from ⅓ to ⅔ times of a thickness of the rigid support layer.

4. The display panel according to any one of claim 1, wherein the patterned part comprises multiple grooves, and the support islands are uniformly arranged.

5. The display panel according to claim 4, wherein each of the grooves penetrates through the rigid support layer in a direction parallel to a bending axis.

6. The display panel according to claim 1, wherein a cross-sectional shape of the groove comprises one or a combination of multiple ones of a square, a rectangle, a triangle, a trapezoid, a semi-circle or a semi-ellipse.

7. The display panel according to claim 1, wherein the display panel body comprises a first bending part and a second bending part, a bending axis of the first bending part crosses a bending axis of the second bending part, the patterned part comprises a first sub-patterned part and a second sub-patterned part, the first sub-patterned part corresponds to the first bending part, and the second sub-patterned part corresponds to the second bending part.

8. The display panel according to claim 7, wherein the bending axis of the first bending part is perpendicular to the bending axis of the second bending part.

9. The display panel according to claim 7, wherein the first sub-patterned part comprises a first groove and a first support island, and the second sub-patterned part comprises a second groove and a second support island; and
the first groove and the second groove are mutually connected together at an intersection of the first sub-patterned part and the second sub-patterned part.

10. The display panel according to claim 9, wherein the first sub-patterned part is axisymmetric about the bending axis of the first bending part; and
the second sub-patterned part is axisymmetric about the bending axis of the second bending part.

11. The display panel according to claim 10, wherein a shape of the first support island is the same as a shape of the second support island.

12. The display panel according to claim 10, wherein each of the first support island and the second support island both have an axisymmetric shape about the bending axis of the first bending part; and
each of the first support island and the second support island both have an axisymmetric shape about the bending axis of the second bending part.

13. The display panel according to claim 10, wherein the first sub-patterned part has a centrosymmetric structure, and the second sub-patterned part has a centrosymmetric structure.

14. The display panel according to claim 1, wherein the groove is disposed on one side of the rigid support layer away from the display panel body.

15. The display panel according to claim 2, wherein the material of the filling part is a hot melt glue.

16. A display terminal, comprising a main terminal body and a display panel, wherein the main terminal body and the display panel are combined together as a whole, and the display panel comprises:
a display panel body comprising at least a bending part and a non-bending part; and
a rigid support layer disposed on a backside of the display panel body and comprising a patterned part corresponding to the bending part, and a smooth part corresponding to the non-bending part;
wherein the patterned part comprises at least one groove and multiple discrete support islands disposed in the groove, and surfaces of the support islands are flush with a surface of the smooth part away from the display panel body.

17. The display terminal according to claim 16, wherein the rigid support layer further comprises a filling part filled into the groove, a surface of the filling part away from the rigid support layer is flush with the surface of the smooth part, and an elastic modulus of a material of the filling part is less than an elastic modulus of the rigid support layer.

18. The display terminal according to claim 16, wherein the display panel body comprises a first bending part and a second bending part, a bending axis of the first bending part crosses a bending axis of the second bending part, the patterned part comprises a first sub-patterned part and a second sub-patterned part, the first sub-patterned part corresponds to the first bending part, and the second sub-patterned part corresponds to the second bending part.

19. The display terminal according to claim 18, wherein the first sub-patterned part is axisymmetric about the bending axis of the first bending part; and
the second sub-patterned part is axisymmetric about the bending axis of the second bending part.

20. The display terminal according to claim 18, wherein the first sub-patterned part has a centrosymmetric structure, and the second sub-patterned part has a centrosymmetric structure.
